(19) United States
(12) Patent Application Publication
(10) Pub. No.: US 2026/0076230 A1
(43) Pub. Date: Mar. 12, 2026

(54) SEMICONDUCTOR PACKAGE WITH POWER LINE

(71) Applicant: SAMSUNG ELECTRONICS CO., LTD., Suwon-si (KR)

(72) Inventor: Hansae LIM, Suwon-si (KR)

(73) Assignee: SAMSUNG ELECTRONICS CO., LTD., Suwon-si (KR)

(21) Appl. No.: 19/084,133

(22) Filed: Mar. 19, 2025

(30) Foreign Application Priority Data
Sep. 12, 2024 (KR) 10-2024-0124994

(51) Int. Cl. H01L 23/498; H01L 23/00; H01L 23/31

(52) U.S. Cl. CPC H10W 70/65; H10W 74/111; H10W 90/724

(57) ABSTRACT

A semiconductor package includes a base substrate, a plurality of power bumps on the base substrate, and a semiconductor chip on the plurality of power bumps. The base substrate includes a first power line in contact with the plurality of power bumps. The first power line includes a first line wiring part extending in a first direction, a second line wiring part extending in the first direction and spaced apart from the first line wiring part in a second direction intersecting the first direction, and a connection wiring part coupling the first line wiring part with the second line wiring part. The semiconductor chip includes a plurality of first power pads at least partially overlapping the first line wiring part, and a plurality of second power pads at least partially overlapping the second line wiring part.

### CROSS-REFERENCE TO RELATED APPLICATIONS

This application claims benefit of priority under 35 U.S.C. § 119 of Korean Patent Application No. 10-2024-0124994, filed on Sep. 12, 2024, the disclosure of which is incorporated by reference herein in its entirety.

### BACKGROUND

### 1. Field

The present disclosure relates generally to a semiconductor package, and more particularly, to a semiconductor package including a semiconductor chip.

### 2. Description of Related Art

An integrated circuit chip may be packaged into a semiconductor package in order to have a suitable form that may be installed in an electronic device, such as, but not limited to, a mobile device (e.g., a smartphone, a cellular phone, a personal digital assistant (PDA), a tablet computer, a laptop computer), a personal computer (PC), a server, a wearable device, a smart appliance (e.g., a television (TV), a refrigerator, a washing machine, or the like), an Internet of Things (IoT) device, or the like. In general, in a semiconductor package, a semiconductor chip may be mounted on a printed circuit board, and/or the semiconductor chip and the printed circuit board may be electrically connected to each other using bonding wires and/or bumps. Recent developments in an electronics industry may be directed towards research for potentially improving the reliability of semiconductor packages.

### SUMMARY

One or more example embodiments of the present disclosure provide a semiconductor package with improved electrical characteristics and reliability, when compared to related semiconductor packages.

According to an aspect of the present disclosure, a semiconductor package includes a base substrate, a plurality of power bumps on the base substrate, and a semiconductor chip on the plurality of power bumps. The base substrate includes a first power line in contact with the plurality of power bumps. The first power line includes a first line wiring part extending in a first direction, a second line wiring part extending in the first direction and spaced apart from the first line wiring part in a second direction intersecting the first direction, and a connection wiring part coupling the first line wiring part with the second line wiring part. The semiconductor chip includes a plurality of first power pads at least partially overlapping the first line wiring part, and a plurality of second power pads at least partially overlapping the second line wiring part. The plurality of power bumps includes a plurality of first power bumps in contact with the first line wiring part, and a plurality of second power bumps in contact with the second line wiring part. The plurality of first power bumps are respectively in contact with the plurality of first power pads. The plurality of second power bumps are respectively in contact with the plurality of second power pads.

According to an aspect of the present disclosure, a semiconductor package includes a base substrate including a first power line, a plurality of power bumps in contact with the first power line, and a semiconductor chip on the plurality of power bumps. The first power line includes a first line wiring part extending in a first direction, a second line wiring part extending in the first direction and spaced apart from the first line wiring part in a second direction intersecting the first direction, and a first connection wiring part coupling the first line wiring part with the second line wiring part. The plurality of power bumps include a plurality of first power bumps in contact with the first line wiring part, and a plurality of second power bumps in contact with the second line wiring part. The plurality of first power bumps include a first circuit power bump. The plurality of second power bumps include a second circuit power bump. The first circuit power bump, the second circuit power bump, and the first connection wiring part at least partially overlap a straight line extending in the second direction.

According to an aspect of the present disclosure, a semiconductor package includes a base substrate, a plurality of power bumps on the base substrate, a signal bump on the base substrate, and a semiconductor chip on the plurality of power bumps and the signal bump. The base substrate includes a first power line in contact with the plurality of power bumps, and a signal line in contact with the signal bump. The first power line includes a first line wiring part extending in a first direction, a second line wiring part extending in the first direction and spaced apart from the first line wiring part in a second direction intersecting the first direction, and a connection wiring part coupling the first line wiring part with the second line wiring part. The semiconductor chip includes a first cell power pad at least partially overlapping the first line wiring part, a first circuit power pad at least partially overlapping the first line wiring part, a second circuit power pad at least partially overlapping the second line wiring part, and a first signal pad at least partially overlapping the signal line. The plurality of power bumps include a cell power bump in contact with the first line wiring part and the first cell power pad, a first circuit power bump in contact with the first line wiring part and the first circuit power pad, and a second circuit power bump in contact with the second line wiring part and the second circuit power pad. The first signal pad is disposed between the first cell power pad and the first circuit power pad. The signal bump is disposed between the cell power bump and the first circuit power bump.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a block diagram illustrating a memory system, according to some embodiments;

FIG. 2 is a block diagram illustrating the semiconductor memory device of FIG. 1, according to some embodiments;

FIG. 3A is a plan view of a semiconductor package, according to some embodiments;

FIG. 3B is a cross-sectional view taken along line A-A′ of FIG. 3A, according to some embodiments;

FIG. 3C is a cross-sectional view taken along line B-B′ of FIG. 3A, according to some embodiments;

FIG. 3D is an enlarged view of region Q1 of FIG. 3A, according to some embodiments;

FIG. 4 is a cross-sectional view of a semiconductor package, according to some embodiments; and

FIG. 5 is a cross-sectional view of a semiconductor package, according to some embodiments.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

The terms “upper,” “middle”, “lower”, or the like may be replaced with terms, such as “first,” “second,” third” to be used to describe relative positions of elements. The terms “first,” “second,” third” may be used to describe various elements but the elements are not limited by the terms and a “first element”may be referred to as a “second element”. Alternatively or additionally, the terms “first”, “second”, “third”, or the like may be used to distinguish components from each other and do not limit the present disclosure. For example, the terms “first”, “second”, “third”, or the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, or the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

Hereinafter, a semiconductor package and a method for manufacturing the same according to embodiments of the present disclosure are described with reference to the accompanying drawings.

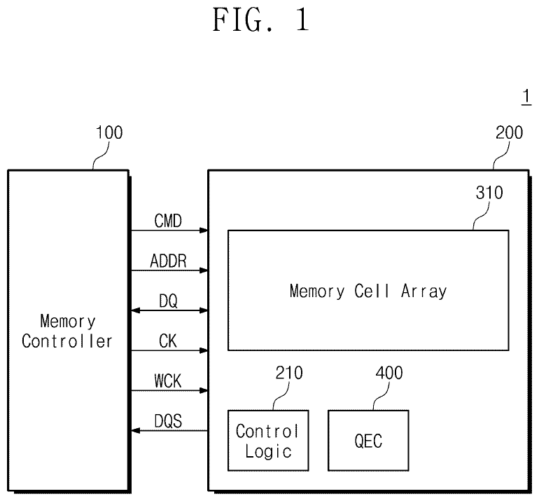

FIG. 1 is a block diagram illustrating a memory system, according to some embodiments.

Referring to FIG. 1, a memory system 1 may include a memory controller 100 and a semiconductor memory device 200.

The memory controller 100 may control overall operation of the memory system 1 and overall data exchange between an external host and the semiconductor device 200. For example, the memory controller 100 may control the semiconductor memory device 200 to read and/or write data in response to a request of a host.

Furthermore, the memory controller 100 may control operation of the semiconductor memory device 200 by applying operation commands for controlling the semiconductor memory device 200. In some embodiments, the semiconductor memory device 200 may be and/or may include, but not be limited to, dynamic random access memory (DRAM), double data rate 4 (DDR4) synchronous DRAM (SDRAM), low power DDR4 (LPDDR4) SDRAM, LPDDR5 SDRAM, or the like, provided with volatile memory cells.

The memory controller 100 may transmit a clock signal (and/or command clock signal) CK, a command CMD, and an address ADDR to the semiconductor memory device 200. When writing a data signal DQ to the semiconductor memory device 200 and/or reading the data signal DQ from the semiconductor memory device 200, the memory controller 100 may provide a data clock signal WCK to the semiconductor memory device 200. When transmitting the data signal DQ to the memory controller 100, the semiconductor memory device 200 may provide a strobe signal DQS to the memory controller 100 together with the data signal DQ.

In an embodiment, the memory controller 100 may be physically implemented by analog and/or digital circuits including one or more of a logic gate, an integrated circuit, a microprocessor, a microcontroller, a memory circuit, a passive electronic component, an active electronic component, an optical component, or the like. For example, a field programmable gate array (FPGA) may be used to implement custom logic that may include the functionality of the memory controller 100. As another example, a processor in combination with a memory may be used to execute one or more instructions to perform the functionality of the memory controller 100.

The semiconductor memory device 200 may be and/or may include a memory cell array 310 in which the data signal DQ may be stored, a control logic circuit 210, and a quadrature error correction (QEC) circuit 400.

The control logic circuit 210 may control operation of the semiconductor memory device 200. In an embodiment, the control logic circuit 210 may be physically implemented by analog and/or digital circuits including one or more of a logic gate, an integrated circuit, a microprocessor, a microcontroller, a memory circuit, a passive electronic component, an active electronic component, an optical component, or the like. For example, an FPGA may be used to implement custom logic that may include the functionality of the control logic circuit 210. As another example, a processor in combination with a memory may be used to execute one or more instructions to perform the functionality of the control logic circuit 210. Alternatively or additionally, at least a portion of the functionality of control logic circuit 210 may be incorporated into the memory controller 100 and/or implemented as instructions to be executed by the memory controller 100.

The QEC circuit 400 may generate correction clock signals having a 90-degree phase difference by adjusting a skew or duty error of input clock signals having a 90-degree phase difference and generated on the basis of the data clock signal WCK. The QEC circuit 400 may be embodied using dedicated timer chips and/or built-in timers within a processing circuit (e.g., the control logic circuit 210, the memory controller 100), and may be programmed to start, stop, and reset based on certain events, such as the detection of a spike. For example, a field programmable gate array (FPGA) may be used to implement custom logic that includes timing functionality.

The number and arrangement of components of the memory system 1 shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Alternatively or additionally, a set of (one or more) components shown in FIG. 1 may be integrated with each other, and/or may be implemented as an integrated circuit, as software, and/or a combination of circuits and software.

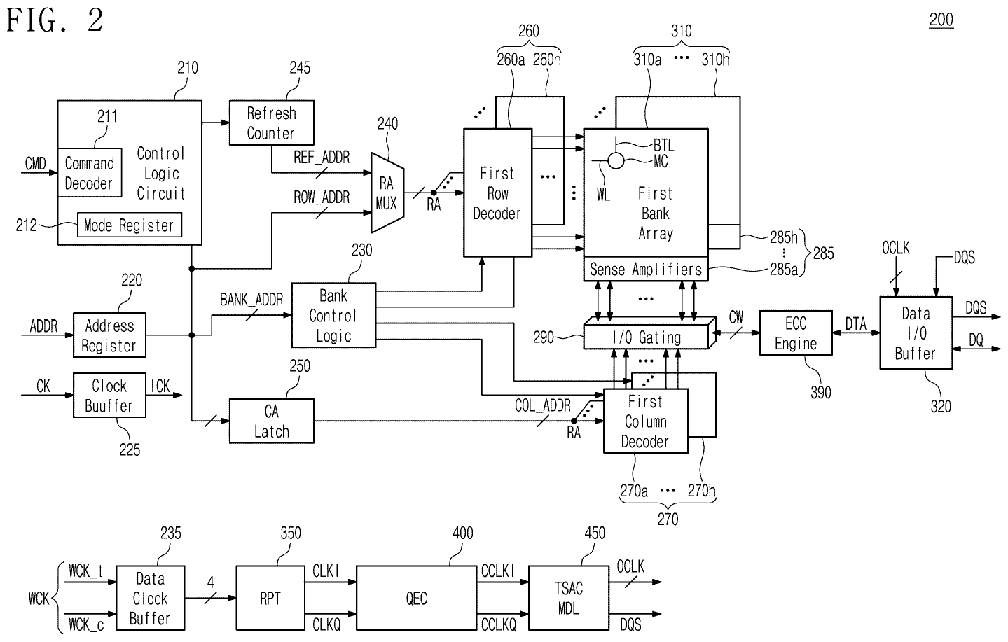

FIG. 2 is a block diagram illustrating the semiconductor memory device of FIG. 1, according to some embodiments.

Referring to FIG. 2, the semiconductor memory device 200 may include the control logic circuit 210, an address register 220, a bank control logic 230, a refresh counter 245, a row address multiplexer 240, a column address (CA) latch 250, a plurality of row decoders 260, a plurality of column decoders 270, the memory cell array 310, a plurality of sense amplifiers 285, an input/output (I/O) gating circuit 290, an error correction code (ECC) engine 390, a clock buffer 225, a data clock buffer 235, a repeater (RPT) 350, the QEC circuit 400, and a tSAC matching delay circuit (TSAC MDL) 450.

The memory cell array 310 may include a plurality of bank arrays (e.g., a first bank array 310a to an h-th bank array 310h, where h is a positive integer greater than one (1)). The plurality of row decoders 260 (e.g., a first row decoder 260a to an h-th row decoder 260h) that may be respectively connected to the plurality of first to h-th bank arrays 310a to 310h. The plurality of column decoder 270 (e.g., a first column decoder 270a to an h-th column decoder 270h) may be respectively connected to the plurality of first to h-th bank arrays 310a to 310h. The plurality of sense amplifiers 285 (e.g., a first sense amplifier 285a to an h-th sense amplifier 285h) may be respectively connected to the plurality of first to h-th bank arrays 310a to 310h.

The plurality of first to h-th bank arrays 310a to 310h, the plurality of sense amplifiers 285, the plurality of column decoders 270, and the plurality of row decoders 260 may each constitute a bank in a plurality of banks (e.g., a first bank to an h-th bank). The plurality of first to h-th bank arrays 310a to 310h may each include a plurality of word lines WL, a plurality of bit lines BTL, and a plurality of memory cells formed at intersections of the plurality of word lines WL and the plurality of bit lines BTL.

The address register 220 may receive the address ADDR including a bank address BANK_ADDR, a row address ROW_ADDR, and a column address COL_ADDR from the memory controller 100. The address register 220 may provide the received bank address BANK_ADDR to the bank control logic 230, provide the received row address ROW_ADDR to the row address multiplexer 240, and provide the received column address COL_ADDR to the column address latch 250.

The bank control logic 230 may generate bank control signals in response to the bank address BANK_ADDR. In response to the bank control signals, a row decoder corresponding to the bank address BANK_ADDR, from among the plurality of row decoders 260, may be activated, and a column decoder corresponding to the bank address BANK_ADDR, from among the plurality of column decoders 270, may be activated.

The row address multiplexer 240 may receive the row address ROW_ADDR from the address register 220 and receive a refresh row address REF_ADDR from the refresh counter 245. The row address multiplexer 240 may selectively output the row address ROW_ADDR or the refresh row address REF_ADDR as a row address RA. The row address RA output from the row address multiplexer 240 may be applied to each of the plurality of row decoders 260.

The refresh counter 245 may sequentially increase and/or decrease the row address REF_ADDR according to control by the control logic circuit 210.

A row decoder activated by the bank control logic 230, from among the plurality of row decoders 260, may activate a word line corresponding to the row address RA by decoding the row address RA output from the row address multiplexer 240. For example, the activated row decoder may apply a word line driving voltage to the word line corresponding to the row address RA.

The column address latch 250 may receive the column address COL_ADDR from the address register 220 and may temporarily store the received column address COL_ADDR. Furthermore, the column address latch 250 may gradually increase the received column address COL_ADDR in a burst mode. The column address latch 250 may apply the temporarily stored or gradually increased column address COL_ADDR to each of the plurality of column decoders 270.

A column decoder activated by the bank control logic 230, from among the plurality of column decoders 270, may activate a sense amplifier corresponding to the bank address BANK_ADDR and the column address COL_ADDR through the corresponding I/O gating circuit 290.

The I/O gating circuit 290 may include, together with a circuit for gating I/O data, an input data mask logic, read data latches for storing data output from the plurality of first to h-th bank arrays 310a to 310h, and write drivers for writing data to the plurality of first to h-th bank arrays 310a to 310h.

A codeword CW to be read from one bank array from among the plurality of bank arrays 310a to 310h may be detected by a sense amplifier corresponding to the one bank array and may be stored in a read data latch. The codeword CW stored in the read data latch may be ECC decoded by the ECC engine 390 and provided to a data I/O buffer 320 as data DTA, and the data I/O buffer 320 may convert the data DTA into the data signal DQ on the basis of an output clock signal OCLK and may provide the data signal DQ to the memory controller 100 together with the strobe signal DQS.

The data signal DQ to be written to one bank array from among the plurality of bank arrays 310a to 310h may be converted into the data DTA by the data I/O buffer 320 and provided to the ECC engine 390, the ECC engine 390 may generate parity bits on the basis of the data DTA and may provide the codeword CW including the data DTA and the parity bits to the I/O gating circuit 290, and the I/O gating circuit 290 may write the codeword CW to a target page of the one bank array through write drivers.

The data I/O buffer 320 may convert the data signal DQ into the data DTA and provide the same to the ECC engine 390 during a write operation, and may convert the data DTA provided from the ECC engine 390 into the data signal DQ on the basis of the output clock signal OCLK and provide the data signal DQ and the strobe signal DQS to the memory controller 100 during a read operation. That is, the data I/O buffer 320 may output the data signal DQ to the outside on the basis of the output clock signal OCLK during a read operation.

The clock buffer 225 may receive a clock signal CK and may generate an internal clock signal ICK by buffering the clock signal CK, and the internal clock signal ICK may be provided to components for processing the command CMD and the address ADDR.

The data clock buffer 235 may receive a pair of differential clock signals WCK_t and WCK_c having opposite phases (e.g., 180 degrees), and may divide the pair of differential clock signals into clock signals having four different phases (e.g., clock signals having a 90-degree phase difference) and output the same.

The repeater 350 may generate the four divided clock signals as a pair of differential input signals. The pair of differential input signals may include a first clock signal CLKI and a second clock signal CLKQ. The first clock signal CLKI and the second clock signal CLKQ may be provided to the QEC circuit 400.

The QEC circuit 400 may correct a skew between the first clock signal CLKI and the second clock signal CLKQ and correct a duty error of the first clock signal CLKI and the second clock signal CLKQ. The QEC circuit 400 may generate a pair of corrected clock signals CCLKI and CCLKQ and provide the same to the TSAC MDL 450.

The TSAC MDL 450 may delay the pair of corrected clock signals CCLKI and CCLKQ for a preset time tSAC and may output the delayed pair of corrected clock signals CCLKI and CCLKQ. The preset time tSAC may be a time needed for data to be output through an output buffer after the pair of differential clock signals WCK_t and WCK_c are input the data clock buffer 235.

The TSAC MDL 450 may generate the output clock signal OCLK and the strobe signal DQS on the basis of the pair of corrected clock signals CCLKI and CCLKQ. The TSAC MDL 450 may provide the output clock signal OCLK and the strobe signal DQS to the data I/O buffer 320.

The control logic circuit 210 may control operation of the semiconductor memory device 200. For example, the control logic circuit 210 may generate control signals so that the semiconductor memory device 200 may perform a write operation and/or a read operation. The control logic circuit 210 may include a command decoder 211 for decoding the command CMD received from the memory controller 100 and a mode register 212 for setting an operation mode of the semiconductor memory device 200.

For example, the command decoder 211 may generate the control signals corresponding to the command CMD by decoding a write enable signal, a row address strobe signal, a column address strobe signal, a chip selection signal, or the like.

The number and arrangement of components of the semiconductor memory device 200 shown in FIG. 2 are provided as an example. In practice, there may be additional components, fewer components, different components, or differently arranged components than those shown in FIG. 2. Furthermore, two or more components shown in FIG. 2 may be implemented within a single component, or a single component shown in FIG. 2 may be implemented as multiple, distributed components. Alternatively or additionally, a set of (one or more) components shown in FIG. 2 may be integrated with each other, and/or may be implemented as an integrated circuit, as software, and/or a combination of circuits and software.

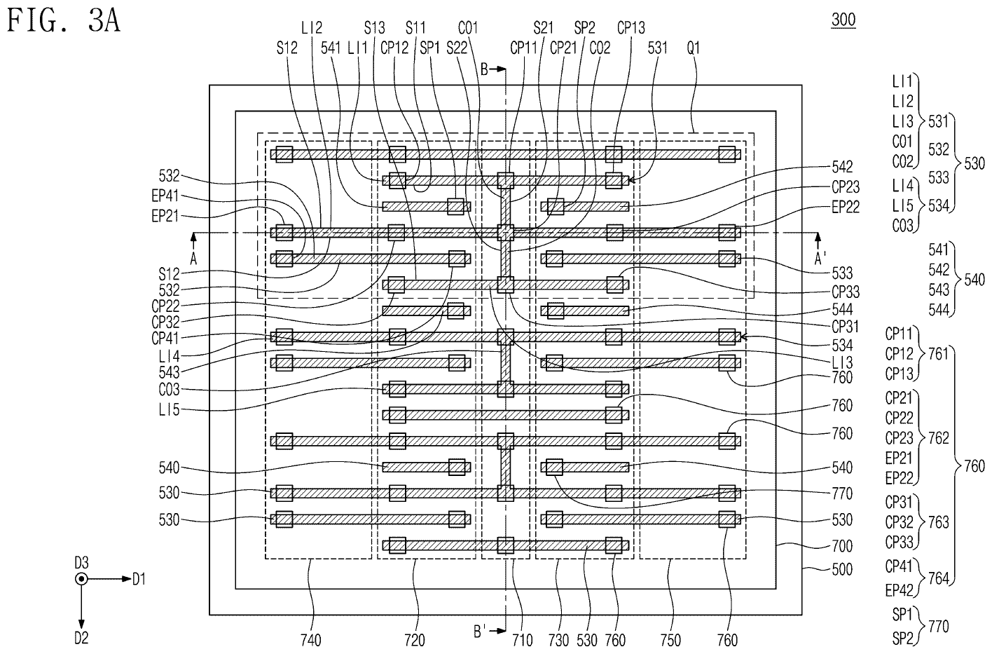

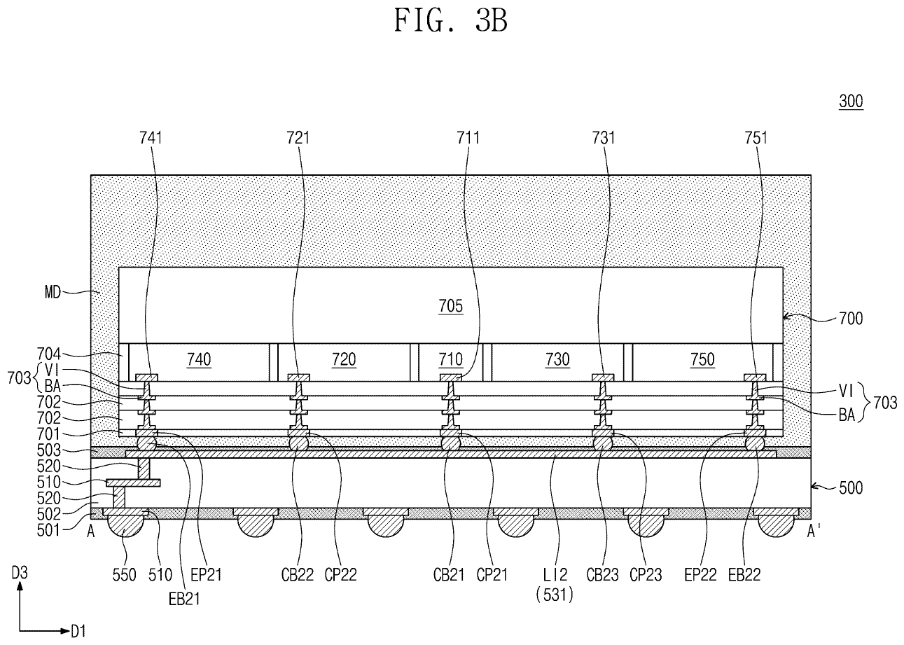

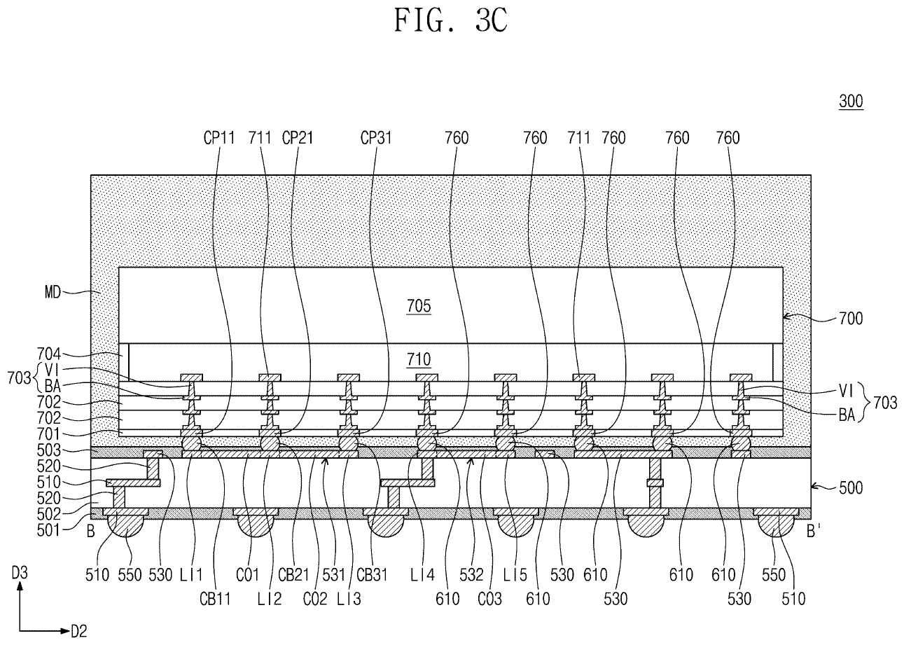

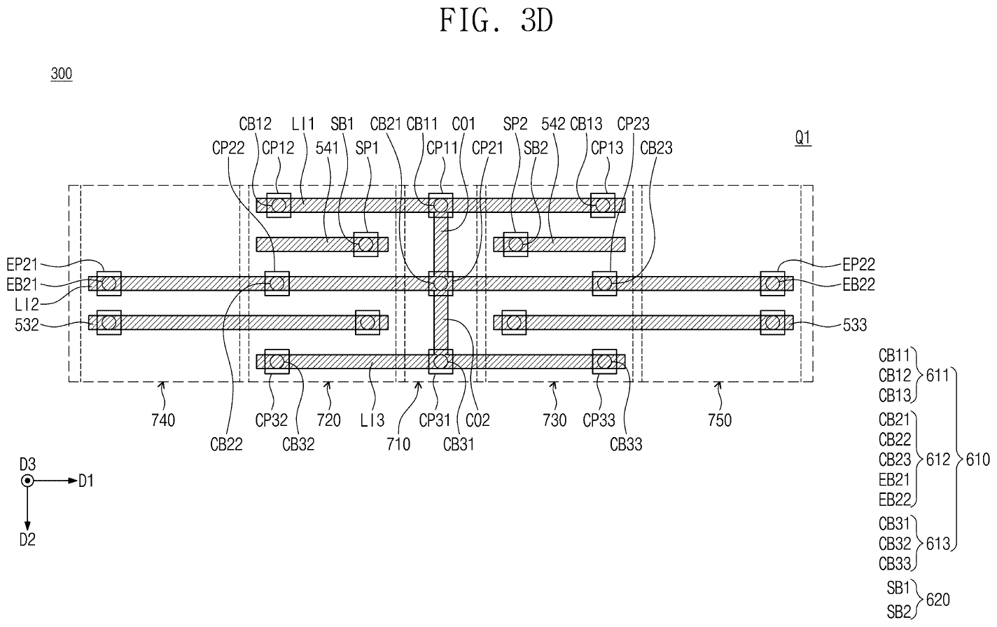

FIG. 3A is a plan view of a semiconductor package, according to some embodiments. FIG. 3B is a cross-sectional view taken along line A-A′ of FIG. 3A, according to some embodiments. FIG. 3C is a cross-sectional view taken along line B-B′ of FIG. 3A, according to some embodiments. FIG. 3D is an enlarged view of region Q1 of FIG. 3A, according to some embodiments.

Referring to FIGS. 3A, 3B, and 3C, the semiconductor package 300 may include a base substrate 500.

The base substrate 500 may be and/or may include a printed circuit board (PCB). The base substrate 500 may have a shape of a plate extending along a plane defined by a first direction D1 and a second direction D2. The first direction D1 and the second direction D2 may intersect each other. For example, the first direction D1 and the second direction D2 may be co-planar directions that are perpendicular to each other.

The base substrate 500 may include a lower insulating layer 501, a body structure 502 on the lower insulating layer 501, an upper insulating layer 503 on the body structure 502, wiring patterns 510, vias 520, power lines 530, and signal lines 540.

The lower insulating layer 501 may be in contact with a lower surface of the body structure 502. The lower insulating layer 501 may include, for example, a solder resist material. However, the present disclosure is not limited in this regard.

The body structure 502 may include, for example, a thermosetting resin, a thermoplastic resin, a photocurable resin, or the like. The body structure 502 may include, for example, a glass fiber or inorganic filler as a reinforcing material. However, the present disclosure is not limited in this regard. In some embodiments, the body structure 502 may be a multi-layer structure including a plurality of layers.

The upper insulating layer 503 may be in contact with an upper surface of the body structure 502. The upper insulating layer 503 may include, for example, a solder resist material. However, the present disclosure is not limited in this regard.

The wiring patterns 510 may be arranged in the body structure 502 and/or may be provided on a lower surface of the body structure 502. The wiring patterns 510 may include a conductive material.

The vias 520 may be arranged in the body structure 502. The vias 520 may electrically connect the wiring patterns 510. The vias 520 may include a conductive material.

The power lines 530 and the signal lines 540 may be provided on an upper surface of the body structure 502. The power lines 530 and the signal lines 540 may be surrounded by the upper insulating layer 503. The power line 530 may be connected to the via 520. The signal line 540 may be connected to the via 520. The power lines 530 and the signal lines 540 may include a conductive material.

In an embodiment, the semiconductor package 300 may further include terminals 550. The terminal 550 may be, for example, a solder ball. The terminals 550 may be in contact with the wiring pattern 510. The terminals 550 may include a conductive material. The semiconductor package 300 may be electrically connected to an external device through the terminals 550.

In an embodiment, the semiconductor package 300 may further include power bumps 610 and signal bumps 620 on the base substrate 500. The power bumps 610 may be in contact with the power line 530. The signal bumps 620 may be in contact with the signal line 540. The power bumps 610 and the signal bumps 620 may include a conductive material.

A semiconductor chip 700 may be provided on the power bumps 610 and the signal bumps 620. The semiconductor chip 700 may include a lower protective film 701, power pads 760, signal pads 770, photo-imageable insulating layers 702, redistribution patterns 703, an insulating structure 704, a first circuit structure 710, a second circuit structure 720, a third circuit structure 730, a first memory cell array 740, a second memory cell array 750, and a substrate 705.

The lower protective film 701 may include an insulating material. For example, the lower protective film 701 may include photo-imageable polyimide. However, the present disclosure is not limited in this regard.

The power pads 760 and the signal pads 770 may be arranged in the lower protective film 701. The power pads 760 and the signal pads 770 may be surrounded by the lower protective film 701. The power pad 760 may overlap the power line 530 in a third direction D3. The power pad 760 may be in contact with the power bump 610. The signal pad 770 may overlap the signal line 540 in the third direction D3. The signal pad 770 may be in contact with the signal bump 620. The power pads 760 and the signal pads 770 may include a conductive material.

The photo-imageable insulating layers 702 may be provided on the lower protective film 701. The photo-imageable insulating layers 702 may be stacked along the third direction D3. The third direction D3 may intersect the first direction D1 and the second direction D2. For example, the third direction D3 may be a vertical direction that is perpendicular to the first direction D1 and the second direction D2.

The photo-imageable insulating layer 702 may include a photo-imageable dielectric (PID) material. The photo-imageable dielectric material may include, but not be limited to, at least one of polybenzoxazole, phenol-based polymer, or benzocyclobutene-based polymer. However, the present disclosure is not limited in this regard. The photo-imageable insulating layer 702 may include a different material from that of the lower protective film 701.

The redistribution patterns 703 may be surrounded by the photo-imageable insulating layer 702. The redistribution patterns 703 may be arranged in the photo-imageable insulating layers 702. The redistribution patterns 703 may each include a base part BA and a via part VI on the base part. A width of the base part BA may be greater than a width of the via part VI. The base part BA may have a line or bar shape, and a via part VI may have a pillar shape. Although differentially described for convenience, the base part BA and the via part VI may be seamlessly connected to each other to have an integrated structure. The redistribution patterns 703 may include a conductive material. For example, the redistribution patterns 703 may include copper (Cu). However, the present disclosure is not limited in this regard. In some embodiments, the redistribution pattern 703 may have a T shape in which the base part BA is disposed on the via part VI. The redistribution patterns 703 may be electrically connected to the power pad 760 or the signal pad 770.

The insulating structure 704 may be provided on the photo-imageable insulating layer 702. The insulating structure 704 may include an insulating material. The insulating structure 704 may be a multi-layer structure including a plurality of insulating layers.

The substrate 705 may be provided on the insulating structure 704. The substrate 705 may be a semiconductor substrate and/or a semiconductor-on-insulator (SOI) substrate. For example, the semiconductor substrate may include silicon (Si), germanium (Ge), or silicon-germanium (Si—Ge). However, the present disclosure is not limited in this regard.

The first circuit structure 710, the second circuit structure 720, the third circuit structure 730, the first memory cell array 740, and the second memory cell array 750 may be surrounded by the insulating structure 704. The first circuit structure 710, the second circuit structure 720, the third circuit structure 730, the first memory cell array 740, and the second memory cell array 750 may be provided on a lower surface of the substrate 705.

The first and second memory cell arrays 740 and 750 may be spaced apart from each other in the first direction D1. The first and second memory cell arrays 740 and 750 may be spaced apart from the first circuit structure 710 in the first direction D1. The first circuit structure 710 may be provided between the first and second memory cell arrays 740 and 750.

The second circuit structure 720 may be disposed between the first memory cell array 740 and the first circuit structure 710. The third circuit structure 730 may be disposed between the second memory cell array 750 and the first circuit structure 710. The first circuit structure 710 may be disposed between the second and third circuit structures 720 and 730.

The first and second memory cell arrays 740 and 750 may include and/or may be similar in many respects to the memory cell array described above with reference to FIGS. 1 and 2, and may include additional features not mentioned above. Consequently, repeated descriptions of the first and second memory cell arrays 740 and 750 described above with reference to FIGS. 1 and 2 may be omitted for the sake of brevity.

The first circuit structure 710 may include, for example, at least one of a data clock buffer, a repeater, a QEC circuit, and a tSAC matching delay circuit. The data clock buffer, the repeater, the QEC circuit, and the tSAC matching delay circuit of the first circuit structure 710 may include and/or may be similar in many respects to the data clock buffer 235, the repeater 350, the QEC circuit 400, and the tSAC matching delay circuit 450 described above with reference to FIGS. 1 and 2, respectively, and may include additional features not mentioned above. Consequently, repeated descriptions of these components described above with reference to FIGS. 1 and 2 may be omitted for the sake of brevity.

The second circuit structure 720 and the third circuit structure 730 may each include, for example, at least one of a control logic circuit, an address register, a bank control logic, a refresh counter, a row address multiplexer, a column address latch, a row decoder, a column decoder, a sense amplifier unit, an I/O gating circuit, an ECC engine, and a clock buffer. In some embodiments, at least one of the control logic circuit, the address register, the bank control logic, the refresh counter, the row address multiplexer, the column address latch, the row decoder, the column decoder, the sense amplifier unit, the I/O gating circuit, the ECC engine, and the clock buffer may be included in only one of the second circuit structure 720 and the third circuit structure 730.

The first circuit structure 710 may delay an input first signal for a preset time to generate a second signal. The generated second signal may be provided to the second circuit structure 720 or the third circuit structure 730. For example, the first signal may be a data clock signal including a pair of differential clock signals.

The second circuit structure 720 may control a write operation and read operation on the first memory cell array 740. The third circuit structure 730 may control a write operation and read operation on the second memory cell array 740.

A molding film MD may be provided on the base substrate 500. The molding film MD may surround the semiconductor chip 700. The molding film MD may include a polymer material. However, the present disclosure is not limited in this regard, and the molding film MD may include other various materials.

The first circuit structure 710 may include a plurality of first circuit pads 711. The second circuit structure 720 may include a plurality of second circuit pads 721. The third circuit structure 730 may include a plurality of third circuit pads 731. The first memory cell array 740 may include a plurality of first cell pads 741. The second memory cell array 750 may include a plurality of second cell pads 751.

The plurality of first circuit pads 711 may be electrically connected to components (e.g., a repeater) of the first circuit structure 710. The plurality of second circuit pads 721 may be electrically connected to components (e.g., a control logic circuit) of the second circuit structure 720. The plurality of third circuit pads 731 may be electrically connected to components (e.g., a control logic circuit) of the third circuit structure 730. The plurality of first cell pads 741 may be electrically connected to components of the first memory cell array 740. The plurality of second cell pads 751 may be electrically connected to components of the second memory cell array 750. The pluralities of first to third circuit pads 711 to 731 and the pluralities of first and second cell pads 741 and 751 may include a conductive material.

The power lines 530 may include a first power line 531. The first power line 531 may include a first line wiring part LI1, a second line wiring part LI2, and a third line wiring part LI3 extending in the first direction D1. The first line wiring part LI1, the second line wiring part LI2, and the third line wiring part LI3 may be spaced apart from each other in the second direction D2.

The first power line 531 may include a first connection wiring part CO1 connected to the first and second line wiring parts LI1 and LI2 and a second connection wiring part CO2 connected to the second and third line wiring parts LI2 and LI3. The first connection wiring part CO1 may be disposed between the first and second line wiring parts LI1 and LI2. The second connection wiring part CO2 may be disposed between the second and third line wiring parts LI2 and LI3. The first and second connection wiring parts CO1 and CO2 may extend in the second direction D2.

The first to third line wiring parts LI1 to LI3 may respectively include sidewalls (e.g., a first sidewall S11, a second sidewall S12, and a third sidewall S13) extending in the first direction D1. The first to third sidewalls S11 to S13 of the first to third line wiring parts LI1 to LI3 may be parallel with the first direction D1.

The first and second connection wiring parts CO1 and CO2 may respectively include sidewalls (e.g., a fourth sidewall S21 and a fifth sidewall S22) extending in the second direction D2. The fourth and fifth sidewalls S21 and S22 of the first and second connection wiring parts CO1 and CO2 may be parallel with the second direction D2.

The sidewall S11 of the first line wiring part LI1 and the sidewall S12 of the second line wiring part LI2 may be connected to the fourth sidewall S21 of the first connection wiring part CO1. The second sidewall S12 of the second line wiring part LI2 and the third sidewall S13 of the third line wiring part LI3 may be connected to the fifth sidewall S22 of the second connection wiring part CO2.

The second line wiring part LI2 may overlap the first to third circuit structures 710 to 730 and the first and second memory cell arrays 740 and 750 in the third direction D3. The first line wiring part LI1 may overlap the first to third circuit structures 710 to 730 in the third direction D3. The first line wiring part LI1 may be disposed between the first and second memory cell arrays 740 and 750. The third line wiring part LI3 may overlap the first to third circuit structures 710 to 730 in the third direction D3. The third line wiring part LI3 may be disposed between the first and second memory cell arrays 740 and 750.

The first connection wiring part CO1 and the second connection wiring part CO2 may overlap the first circuit structure 710 in the third direction D3. The first connection wiring part CO1 and the second connection wiring part CO2 may not overlap the second and third circuit structures 720 and 730 and the first and second memory cell arrays 740 and 750 in the third direction D3. The first connection wiring part CO1 and the second connection wiring part CO2 may be arranged between the second and third circuit structures 720 and 730.

Although the first to third line wiring parts L1 to LI3 and the first and second connection wiring parts CO1 and CO2 have been differentially described for convenience, the first to third line wiring parts L1 to LI3 and the first and second connection wiring parts CO1 and CO2 may be seamlessly connected to each other to form an integrated structure.

A length of each of the line wiring parts LI1 to LI3 in the first direction D1 may be greater than a length of each of the connection wiring parts CO1 and CO2 in the first direction D1. A length of each of the line wiring parts LI1 to LI3 in the second direction D2 may be less than a length of each of the connection wiring parts CO1 and CO2 in the second direction D2.

The power lines 530 may further include a second power line 532 and a third power line 533 arranged between the second and third line wiring parts LI2 and LI3 of the first power line 531. The second power line 532 and the third power line 533 may extend in the first direction D1. The second power line 532 and the third power line 533 may be spaced apart from each other in the first direction D1. The second connection wiring part CO2 of the first power line 531 may be disposed between the second power line 532 and the third power line 533.

The signal lines 540 may include a first signal line 541 and a second signal line 542 arranged between the first and second line wiring parts LI1 and LI2 of the first power line 531. The first signal line 541 and the second signal line 542 may be spaced apart from each other in the first direction D1. The first signal line 541 and the second signal line 542 may extend in the first direction D1. The first connection wiring part CO1 of the first power line 531 may be disposed between the first signal line 541 and the second signal line 542.

The power lines 530 may include a fourth power line 534 spaced apart from the first power line 531 in the second direction D2. The fourth power line 534 may include a fourth line wiring part LI4, a fifth line wiring part LI5, and a third connection part CO3.

The signal lines 540 may include a third signal line 543 and a fourth signal line 544 between the first and fourth power lines 531 and 534. The third signal line 543 and the fourth signal line 544 may be arranged between the third line wiring part LI3 of the first power line 531 and the fourth line wiring part LI4 of the fourth power line 534. The first to third connection wiring parts CO1 to CO3 may be arranged between the third signal line 543 and the fourth signal line 544.

The power pads 760 may include first power pads 761 overlapping the first line wiring part LI1 of the first power line 531 in the third direction D3, second power pads 762 overlapping the second line wiring part LI2 of the first power line 531 in the third direction D3, and third power pads 763 overlapping the third line wiring part LI3 of the first power line 531 in the third direction D3.

The first power pads 761 may include a first circuit power pad CP11 overlapping the first circuit structure 710 in the third direction D3, a second circuit power pad CP12 overlapping the second circuit structure 720 in the third direction D3, and a third circuit power pad CP13 overlapping the third circuit structure 730 in the third direction D3. The first circuit power pad CP11 may be disposed between the second and third circuit power pads CP12 and CP13. The first circuit power pad CP11 may overlap the first connection wiring part CO1 in the third direction D3. The first to third circuit power pads CP11 to CP13 of the first power pads 761 may be arranged spaced apart from each other in the first direction D1.

The second power pads 762 may include a fourth circuit power pad CP21 overlapping the first circuit structure 710 in the third direction D3, a fifth circuit power pad CP22 overlapping the second circuit structure 720 in the third direction D3, a sixth circuit power pad CP23 overlapping the third circuit structure 730 in the third direction D3, a first cell power pad EP21 overlapping the first memory cell array 740 in the third direction D3, and a second cell power pad EP22 overlapping the second memory cell array 750 in the third direction D3. The fourth to sixth circuit power pads CP21 to CP23 may be arranged between the first and second cell power pads EP21 and EP22. The fourth circuit power pad CP21 may overlap the first connection wiring part CO1 and the second connection wiring part CO2 in the third direction D3. The fourth to sixth power pads CP21 to CP23 and the first and second cell power pads EP21 and EP22 of the second power pads 762 may be arranged spaced apart from each other in the first direction D1.

The third power pads 763 may include a seventh circuit power pad CP31 overlapping the first circuit structure 710 in the third direction D3, an eighth circuit power pad CP32 overlapping the second circuit structure 720 in the third direction D3, and a ninth circuit power pad CP33 overlapping the third circuit structure 730 in the third direction D3. The seventh circuit power pad CP31 may be disposed between the eighth and ninth circuit power pads CP32 and CP33. The seventh circuit power pad CP31 may overlap the second connection wiring part CO2 in the third direction D3. The seventh to ninth circuit power pads CP31, CP32, and CP33 of the third power pads 763 may be arranged spaced apart from each other in the first direction D1.

The signal pads 770 may include a first signal pad SP1 overlapping the first signal line 541 in the third direction D3 and a second signal pad SP2 overlapping the second signal line 542 in the third direction D3. The first signal pad SP1 may be disposed between the first and second circuit power pads CP11 and CP12 of the first power pads 761. The second signal pad SP2 may be disposed between the first and third circuit power pads CP11 and CP13 of the first power pads 761. The first connection wiring part CO1 of the first power line 531 may be disposed between the first and second signal pads SP1 and SP2.

The power pads 760 may further include fourth power pads 764 overlapping the second power line 532 in the third direction D3. The fourth power pads 764 may include a tenth circuit power pad CP41 overlapping the second circuit structure 720 in the third direction D3 and a third cell power pad EP41 overlapping the first memory cell array 740 in the third direction D3. The tenth circuit power pad CP41 of the fourth power pads 764 may be disposed between the fourth and fifth circuit power pads CP21 and CP22 of the second power pads 762.

Referring to FIGS. 3B, 3C, and 3D, the power bumps 610 may include first power bumps 611, second power bumps 612, and third power bumps 613 that are in contact with the first power line 531. The first power bumps 611 may be in contact with the first line wiring part LI1 of the first power line 531. The second power bumps 612 may be in contact with the second line wiring part LI2 of the first power line 531. The third power bumps 613 may be in contact with the third line wiring part LI3 of the first power line 531.

The first power bumps 611 may include a first circuit power bump CB11 that is in contact with the first circuit power pad CP11, a second circuit power bump CB12 that is in contact with the second circuit power pad CP12, and a third circuit power bump CB13 that is in contact with the third circuit power pad CP13. The first to third circuit power bumps CB11 to CB13 of the first power bumps 611 may be arranged spaced apart from each other in the first direction D1.

The second power bumps 612 may include a fourth circuit power bump CB21 that is in contact with the fourth circuit power pad CP21, a fifth circuit power bump CB22 that is in contact with the fifth circuit power pad CP22, a sixth circuit power bump CB23 that is in contact with the sixth circuit power pad CP23, a first cell power bump EB21 that is in contact with the first cell power pad EP21, and a second cell power bump EB22 that is in contact with the second cell power pad EP22. The fourth to sixth circuit power bumps CB21, CB22, and CB23 and the first and second cell power bumps EB21 and EB22 of the second power bumps 612 may be arranged spaced apart from each other in the first direction D1.

The third power bumps 613 may include a seventh circuit power bump CB31 that is in contact with the seventh circuit power pad CP31, an eighth circuit power bump CB32 that is in contact with the eighth circuit power pad CP32, and a ninth circuit power bump CB33 that is in contact with the ninth circuit power pad CP33. The seventh to ninth circuit power bumps CB31 to CB33 of the third power bumps 613 may be arranged spaced apart from each other in the first direction D1.

The signal bumps 620 may include a first signal bump SB1 that is in contact with the first signal line 541 and the first signal pad SP1 and a second signal bump SB2 that is in contact with the second signal line 542 and the second signal pad SP2. The first signal bump SB1 may be disposed between the first and second circuit power bumps CB11 and CB12. The second signal bump SB2 may be disposed between the first and third circuit power bumps CB11 and CB13.

The first circuit power bump CB11, the first connection wiring part CO1, the fourth circuit power bump CB21, the second connection wiring part CO2, and the seventh circuit power bump CB31 may overlap, in the third direction D3, in a straight line extending in the second direction D2.

The first circuit power pad CP11, the first connection wiring part CO1, the fourth circuit power pad CP21, the second connection wiring part CO2, and the seventh circuit power pad CP31 may overlap, in the third direction D3, in a straight line extending in the second direction D2.

The power pad 760 may overlap the pluralities of first to third circuit pads 711 to 731 or the pluralities of first and second cell pads 741 and 751 in the third direction D3. For example, the first circuit power pad CP11 may overlap the plurality of first circuit pads 711 in the third direction D3. The power pad 760 may be electrically connected to the pluralities of first to third circuit pads 711 to 731 or the pluralities of first and second cell pads 741 and 751 through the redistribution patterns 703.

The signal pad 770 may overlap the plurality of second circuit pads 721 or the plurality of third circuit pads 731 in the third direction D3. The signal pad 770 may be electrically connected to the plurality of second circuit pads 721 or the plurality of third circuit pads 731 through the redistribution patterns 703.

Referring to FIGS. 3A, 3B, 3C, and 3D, the first circuit structure 710, the second circuit structure 720, the third circuit structure 730, the first memory cell array 740, and the second memory cell array 750 may each be electrically connected to the power line 530 through the power bump 610, the power pad 760, and the redistribution pattern 703. A power supply voltage (e.g., VDD or VDDQ) and/or a ground voltage (e.g., VSS) may be provided to each of the first circuit structure 710, the second circuit structure 720, the third circuit structure 730, the first memory cell array 740, and the second memory cell array 750 through the power line 530, the power bump 610, the power pad 760, and the redistribution pattern 703. That is, the first circuit structure 710, the second circuit structure 720, the third circuit structure 730, the first memory cell array 740, and the second memory cell array 750 through the power line 530, the power bump 610, the power pad 760, and the redistribution pattern 703 may be configured to receive at least one of the power supply voltage and/or the ground voltage. For example, the first circuit structure 710 may be provided with the power supply voltage or ground voltage from the first power line 531 through the first circuit power bump CB11, the first circuit power pad CP11, and the redistribution patterns 703.

The second circuit structure 720 and the third circuit structure 730 may each be electrically connected to the signal line 540 through the signal bump 620, the signal pad 770, and the redistribution pattern 703. A signal (e.g., a command signal, address signal, data signal, clock signal, data clock signal, or the like) may be provided to the second circuit structure 720 or the third circuit structure 730 through the signal line 540, the signal bump 620, the signal pad 770, and the redistribution pattern 703. For example, the second circuit structure 720 may be provided with a signal from the first signal line 541 through the first signal bump SB1, the first signal pad SP1, and the redistribution patterns 703.

Since a semiconductor package, according to some embodiments, may include the first to third circuit power pads CP11 to CP31, the first to third circuit power bumps CB11 to CB31, and the power lines 530 overlapping the first circuit structure 710 in the third direction D3, a power supply voltage may be directly provided to the first circuit structure 710. Accordingly, supply of power to the data clock buffer, the repeater, the QEC circuit, and the tSAC matching delay circuit included in the first circuit structure 710 may be improved, and an IR drop phenomenon that may occur on the data clock buffer, the repeater, the QEC circuit, and the tSAC matching delay circuit may be suppressed, when compared to related semiconductor packages.

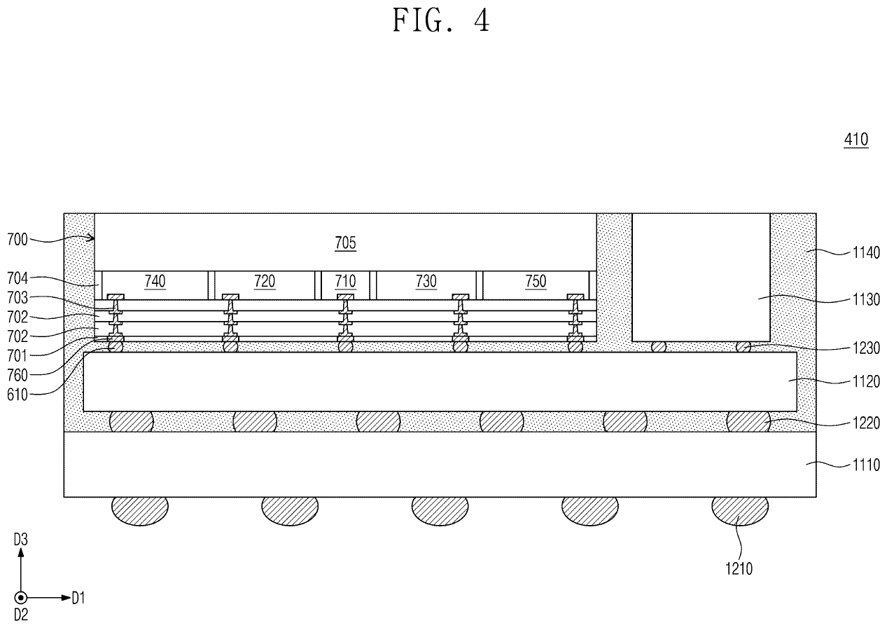

FIG. 4 is a cross-sectional view of a semiconductor package, according to some embodiments. The semiconductor package 410 according to FIG. 4 may include and/or may be similar in many respects to the semiconductor package 300 described above with reference to FIGS. 3A to 3D, and may include additional features not mentioned above. Consequently, repeated descriptions of the semiconductor package 410 described above with reference to FIGS. 3A to 3D may be omitted for the sake of brevity.

Referring to FIG. 4, the semiconductor package 410 may include first terminals 1210, a package substrate 1110, second terminals 1220, an interposer 1120, third terminals 1230, a semiconductor chip 700, power bumps 610, signal bumps, a processor chip 1130, and a package molding film 1140.

The semiconductor chip 700, the power bumps 610, and the signal bumps of FIG. 4 may include and/or may be similar in many respects to the semiconductor chip 700, the power bumps 610, and the signal bumps 620 described above with reference to FIGS. 3A to 3D, and may include additional features not mentioned above. Consequently, repeated descriptions of these components described above with reference to FIGS. 3A to 3D may be omitted for the sake of brevity.

The package substrate 1110 may be provided on the first terminals 1210. The package substrate 1110 may be and/or may include a PCB, for example. The semiconductor package may be mounted on an external device (e.g., a main board) through the first terminals 1210. The first terminals 1210 may include a conductive material.

The interposer 1120 may be provided on the package substrate 1110. The interposer 1120 may be a silicon interposer, for example. The second terminals 1220 electrically connecting the package substrate 1110 and the interposer 1120 may be provided. The second terminals 1220 may include a conductive material.

The processor chip 1130 may be provided on the interposer 1120. For example, the processor chip 1130 may be and/or may include a graphic processing unit (GPU), central processing unit (CPU), or the like. The third terminals 1230 electrically connecting the processor chip 1130 and the interposer 1120 may be provided. The third terminals 1230 may include a conductive material.

The power bumps 610 and signal bumps may be provided on the interposer 1120. The semiconductor chip 700 may be provided on the power bumps 610 and the signal bumps. The interposer 1120 may include a power line electrically connected to the power bump 610 and the power pad 760. The interposer 1120 may include a signal line electrically connected to the signal bumps and signal pads.

The package molding film 1140 may be provided on the package substrate 1110. The package molding film 1140 may surround the interposer 1120, the processor chip 1130, and the semiconductor chip 700. The package molding film 1140 may include a polymer material.

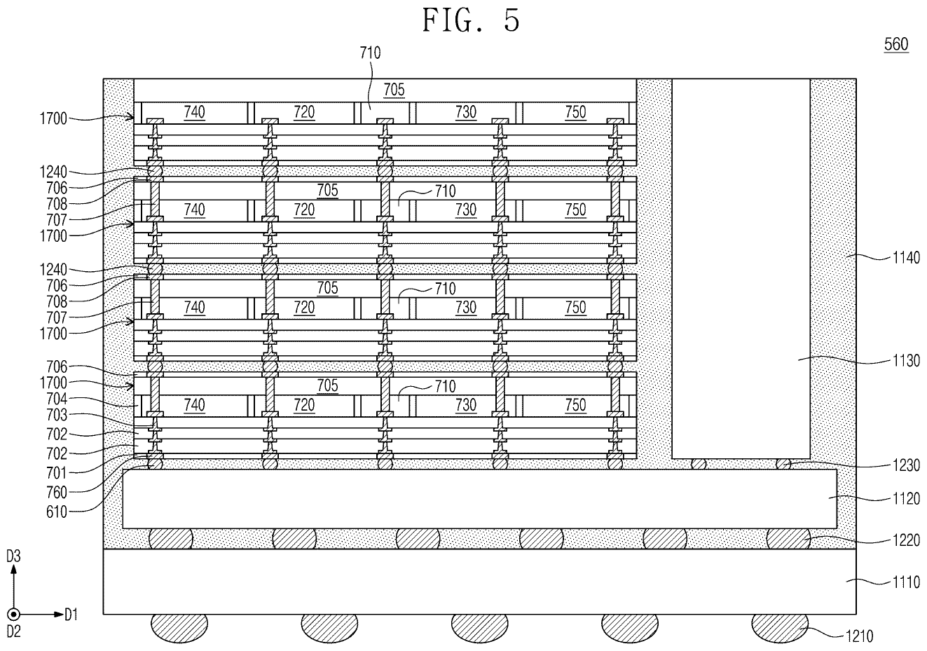

FIG. 5 is a cross-sectional view of a semiconductor package, according to some embodiments. The semiconductor package 560 of FIG. 5 may include and/or may be similar in many respects to the semiconductor packages 300 and 410 described above with reference to FIGS. 3A to 4, and may include additional features not mentioned above. Consequently, repeated descriptions of the semiconductor package 560 described above with reference to FIGS. 3A to 4 may be omitted for the sake of brevity.

Referring to FIG. 5, the semiconductor package 560 may include semiconductor chips 1700 stacked on the interposer 1120. The semiconductor chips 1700 may each include the power pads 760, signal pads, the lower protective film 701, the photo-imageable insulating layers 702, the redistribution patterns 703, the insulating structure 704, the first circuit structure 710, the second circuit structure 720, the third circuit structure 730, the first memory cell array 740, the second memory cell array 750, and the substrate 705.

The semiconductor chips 1700, except for the uppermost semiconductor chip 1700, may each include through-vias 707, an upper protective film 706, and upper pads 708. The through-via 707 may extend in the third direction D3 and penetrate the substrate 705. The through-via 707 may extend through the first circuit structure 710, the second circuit structure 720, the third circuit structure 730, the memory cell array 740, or the second memory cell array 750. The through-via 707 may include a conductive material.

The upper protective film 706 may be provided on the substrate 705. The upper protective film 706 may include an insulating material.

The upper pads 708 may be provided in the upper protective film 706. The upper pad 708 may be provided on the through-via 707. The upper pads 708 may include a conductive material.

The through-via 707 may electrically connect the upper pad 708 and the power pad 760. The through-via 707 may electrically connect the upper pad 708 and a signal pad.

Connection bumps 1240 may be provided between the semiconductor chips 1700. The connection bump 1240 may be in contact with the upper pad 708 and the power pad 760 or the upper pad 708 and the signal pad. The connection bump 1240 may include a conductive material.

Power may be provided from the interposer 1120 to the uppermost semiconductor chip 1700 through the through-via 707, the upper pad 708, and the connection bump 1240. A signal may be provided from the interposer 1120 to the uppermost semiconductor chip 1700 through the through-via 707, the upper pad 708, and the connection bump 1240.

A semiconductor package, according to embodiments of the present disclosure, may suppress an IR drop phenomenon that may occur in a circuit structure, when compared to related semiconductor packages.

Although embodiments of the present disclosure have been described with reference to the accompanying drawings, those of ordinary skill in the art could easily understand that the present disclosure may be carried out in other specific forms without changing the technical concept or essential features. Therefore, the above embodiments should be considered illustrative and should not be construed as limiting.

What is claimed is:

1. A semiconductor package, comprising:
a base substrate;
a plurality of power bumps on the base substrate; and
a semiconductor chip on the plurality of power bumps,
wherein the base substrate comprises a first power line in contact with the plurality of power bumps,
wherein the first power line comprises:
a first line wiring part extending in a first direction;
a second line wiring part extending in the first direction and spaced apart from the first line wiring part in a second direction, the second direction intersecting the first direction; and
a connection wiring part coupling the first line wiring part with the second line wiring part,
wherein the semiconductor chip comprises:
a plurality of first power pads at least partially overlapping the first line wiring part; and
a plurality of second power pads at least partially overlapping the second line wiring part,
wherein the plurality of power bumps comprise:
a plurality of first power bumps in contact with the first line wiring part; and
a plurality of second power bumps in contact with the second line wiring part,
wherein the plurality of first power bumps are respectively in contact with the plurality of first power pads, and
wherein the plurality of second power bumps are respectively in contact with the plurality of second power pads.

2. The semiconductor package of claim 1, wherein a sidewall of the first line wiring part and a sidewall of the second line wiring part are parallel with the first direction, and
wherein a sidewall of the connection wiring part is coupled with the sidewall of the first line wiring part and the sidewall of the second line wiring part, and
wherein the sidewall of the connection wiring part is parallel with the second direction.

3. The semiconductor package of claim 1, wherein at least one of the plurality of first power pads at least partially overlaps the connection wiring part, and
wherein at least one of the plurality of second power pads at least partially overlaps the connection wiring part.

4. The semiconductor package of claim 1, wherein the base substrate further comprises a second power line disposed between the first line wiring part and the second line wiring part and extending in the first direction,
wherein the second power line is spaced apart from the connection wiring part in the first direction,
wherein the semiconductor chip further comprises a plurality of third power pads at least partially overlapping the second power line,
wherein the plurality of power bumps further comprise a plurality of third power bumps in contact with the second power line, and
wherein the plurality of third power bumps are respectively in contact with the plurality of third power pads.

5. The semiconductor package of claim 1, wherein the base substrate further comprises a signal line extending in the first direction,
wherein the semiconductor chip further comprises a signal pad at least partially overlapping the signal line, and
wherein the semiconductor package further comprises a signal bump in contact with the signal pad and the signal line.

6. The semiconductor package of claim 5, wherein the semiconductor chip comprises:
a memory cell array;
a first circuit structure spaced apart from the memory cell array; and
a second circuit structure between the first circuit structure and the memory cell array,
wherein the plurality of first power pads comprise:
a circuit power pad at least partially overlapping the first circuit structure; and
a cell power pad at least partially overlapping the memory cell array, and
wherein the signal pad is disposed between the circuit power pad and the cell power pad.

7. The semiconductor package of claim 6, wherein the first circuit structure is configured to:
receive a first signal for a preset time;
generate a second signal by delaying the first signal; and
receive, through the circuit power pad, at least one of a power supply voltage or a ground voltage.

8. The semiconductor package of claim 7, wherein the second circuit structure comprises a control logic circuit configured to control a write operation and read operation on the memory cell array, and
wherein the second circuit structure is configured to receive, through the signal pad, a signal.

9. A semiconductor package, comprising:
a base substrate comprising a first power line;
a plurality of power bumps in contact with the first power line; and
a semiconductor chip on the plurality of power bumps,
wherein the first power line comprises:
a first line wiring part extending in a first direction;
a second line wiring part extending in the first direction and spaced apart from the first line wiring part in a second direction, the second direction intersecting the first direction; and
a first connection wiring part coupling the first line wiring part with the second line wiring part,
wherein the plurality of power bumps comprise:
a plurality of first power bumps in contact with the first line wiring part; and
a plurality of second power bumps in contact with the second line wiring part,
wherein the plurality of first power bumps comprise a first circuit power bump,
wherein the plurality of second power bumps comprise a second circuit power bump, and
wherein the first circuit power bump, the second circuit power bump, and the first connection wiring part at least partially overlap a straight line extending in the second direction.

10. The semiconductor package of claim 9, wherein the plurality of first power bumps further comprise a cell power bump spaced apart from the first circuit power bump in the first direction.

11. The semiconductor package of claim 10, wherein the base substrate further comprises a signal line,
wherein the semiconductor package further comprises a signal bump on the signal line, and
wherein the signal bump is disposed between the first circuit power bump and the cell power bump.

12. The semiconductor package of claim 11, wherein the semiconductor chip is configured to:
receive at least one a power supply voltage or a ground voltage through the first circuit power bump and the cell power bump; and
receive a signal through the signal bump.

13. The semiconductor package of claim 10, wherein the first circuit power bump, the second circuit power bump, and the cell power bump are coupled with each other.

14. The semiconductor package of claim 9, wherein the base substrate further comprises a second power line spaced apart from the first power line, and
wherein the second power line comprises:
a third line wiring part extending in the first direction;
a fourth line wiring part spaced apart from the third line wiring part and extending in the first direction; and
a second connection wiring part coupling the third line wiring part with the fourth line wiring part.

15. The semiconductor package of claim 14, further comprising:
a plurality of signal lines between the first power line and the second power line,
wherein the first connection wiring part and the second connection wiring part are disposed between the plurality of signal lines.

16. A semiconductor package, comprising:
a base substrate;
a plurality of power bumps on the base substrate;
a signal bump on the base substrate; and
a semiconductor chip on the plurality of power bumps and the signal bump,
wherein the base substrate comprises:
a first power line in contact with the plurality of power bumps; and
a signal line in contact with the signal bump,
wherein the first power line comprises:
a first line wiring part extending in a first direction;
a second line wiring part extending in the first direction and spaced apart from the first line wiring part in a second direction, the second direction intersecting the first direction; and
a connection wiring part coupling the first line wiring part with the second line wiring part,
wherein the semiconductor chip comprises:
a first cell power pad at least partially overlapping the first line wiring part;
a first circuit power pad at least partially overlapping the first line wiring part;
a second circuit power pad at least partially overlapping the second line wiring part; and
a first signal pad at least partially overlapping the signal line,
wherein the plurality of power bumps comprise:
a cell power bump in contact with the first line wiring part and the first cell power pad;
a first circuit power bump in contact with the first line wiring part and the first circuit power pad; and
a second circuit power bump in contact with the second line wiring part and the second circuit power pad,
wherein the first signal pad is disposed between the first cell power pad and the first circuit power pad, and
wherein the signal bump is disposed between the cell power bump and the first circuit power bump.

17. The semiconductor package of claim 16, wherein the semiconductor chip further comprises:
a first circuit structure;
a first memory cell array spaced apart from the first circuit structure;
a second circuit structure between the first circuit structure and the first memory cell array;
a first redistribution pattern coupling the first circuit structure with the first circuit power pad;
a second redistribution pattern coupling the second circuit structure with the first signal pad; and
a third redistribution pattern coupling the first memory cell array with the first cell power pad.

18. The semiconductor package of claim 17, wherein the semiconductor chip further comprises a photo-imageable insulating layer at least partially surrounding the first redistribution pattern, the second redistribution pattern, and the third redistribution pattern.

19. The semiconductor package of claim 17, wherein the first circuit structure is configured to:
receive a first signal for a preset time;
generate a second signal by delaying the first signal; and
receive at least one of a power supply voltage or a ground voltage through the first circuit power bump, the first circuit power pad, and the first redistribution pattern,
wherein the second circuit structure comprises a control logic circuit configured to:
control a write operation and read operation on the first memory cell array, and
receive a third signal through the signal bump, the first signal pad, and the second redistribution pattern.

20. The semiconductor package of claim 16, wherein the semiconductor chip further comprises:
a first circuit structure at least partially overlapping the first circuit power pad and the second circuit power pad;
a first memory cell array at least partially overlapping the first cell power pad and spaced apart from the first circuit structure;
a second circuit structure at least partially overlapping the first signal pad and disposed between the first circuit structure and the first memory cell array;
a second memory cell array spaced apart from the first circuit structure;
a third circuit structure between the first circuit structure and the second memory cell array;
a second cell power pad at least partially overlapping the second memory cell array; and
a second signal pad at least partially overlapping the third circuit structure,
wherein the first circuit structure is configured to:
receive a first signal for a preset time, and
generate a second signal by delaying the first signal,
receive at least one of a power supply voltage or a ground voltage through the first circuit power pad and the second circuit power pad,
wherein the second circuit structure comprises a first control logic circuit configured to:
control a write operation and read operation on the first memory cell array, and
receive a third signal through the first signal pad,
wherein the third circuit structure comprises a second control logic circuit configured to:
control a write operation and read operation on the second memory cell array, and
receive a fourth signal through the second signal pad,
wherein the first memory cell array is configured to receive at least one of the power supply voltage or the ground voltage through the first cell power pad, and
wherein the second memory cell array is configured to receive at least one of the power supply voltage or the ground voltage through the second cell power pad.
